(19) United States
(12) Patent Application Publication
(10) Pub. No.: US 2023/0115130 A1
(43) Pub. Date: Apr. 13, 2023

(54) METHODS FOR PREPARING METAL SILICIDES

(71) Applicant: Applied Materials, Inc., Santa Clara, CA (US)

(72) Inventors: Tom Ho Wing YU, Campbell, CA (US); Nobuyuki SASAKI, Santa Clara, CA (US)

(21) Appl. No.: 17/500,749

(22) Filed: Oct. 13, 2021

(51) Int. Cl. H01L 21/285; H01L 21/02

(52) U.S. Cl. CPC H01L 21/28518; H01L 21/02068

(57) ABSTRACT

Embodiments of the present disclosure generally relate to methods for forming or otherwise producing metal silicides on a silicon surface of substrate. Exemplary metal silicides can be or include titanium silicide, cobalt silicide, nickel silicide, molybdenum silicide, or alloys thereof. In one or more embodiments, a method of forming a metal silicide is provided and includes removing a native oxide from a substrate to reveal a silicon surface of the substrate during a cleaning process, depositing a metallic layer on the silicon surface during a deposition process, and heating the substrate contained within a process region containing hydrogen gas during a silicidation process to produce a metal silicide layer on the substrate from the metallic layer and the silicon surface.

### BACKGROUND

### Field

Embodiments of the present disclosure generally relate to microelectronic fabrication, and more specifically, relate to methods for forming metal silicides on a substrate.

### Description of the Related Art

Metal silicide layers or films, such as titanium silicide or nickel silicide, are currently used in various electronic devices. For example, metal silicide layers or films are used in source/drain (S/D) contact areas for resistor-capacitor (RC) reduction in nMOS and pMOS. Agglomeration can occur on or at the metal silicide film when exposed to high temperatures (e.g., greater than 700° C.). Agglomeration occurs in which polysilicon grains tend to spheroidize between grain boundaries and cause film discontinuity and greater electrical resistivity for the metal silicide film.

Therefore, there is a need for an improved method to prepare metal silicides with a reduced electrical resistance over traditional metal silicides.

### SUMMARY

Embodiments of the present disclosure generally relate to methods for forming or otherwise producing metal silicides on a silicon surface of substrate. Exemplary metal silicides can be or include titanium silicide, cobalt silicide, nickel silicide, molybdenum silicide, or alloys thereof. In one or more embodiments, a method of forming a metal silicide is provided and includes removing a native oxide from a substrate to reveal a silicon surface of the substrate during a cleaning process, depositing a metallic layer on the silicon surface during a deposition process, and heating the substrate contained within a process region containing hydrogen gas (H₂) during a silicidation process to produce a metal silicide layer on the substrate from the metallic layer and the silicon surface.

In some embodiments, a method of forming a metal silicide is provided and includes removing a native oxide from a substrate to reveal a silicon surface of the substrate during a cleaning process and depositing a metallic layer containing titanium on the silicon surface during a deposition process. The method also includes heating the substrate contained within a process region containing hydrogen gas during a silicidation process to produce a metal silicide layer containing titanium on the substrate from the metallic layer and the silicon surface. The metal silicide layer has an electrical resistance of less than 50 Ω/sq.

In other embodiments, a method of forming a metal silicide is provided and includes exposing a substrate to a plasma to remove a native oxide disposed on the substrate and to reveal a silicon surface of the substrate and depositing a metallic layer containing titanium on the silicon surface during a PVD process, wherein the substrate is maintained at a temperature of about 23° C. to about 450° C. during the PVD process. The method also includes exposing the substrate to a silicidation process to produce a metal silicide layer containing titanium on the substrate from the metallic layer and the silicon surface. The silicidation process includes heating the substrate within a process region containing hydrogen gas to a temperature of about 500° C. to about 1,100° C. The metal silicide layer has an electrical resistance of about 4 Ω/sq to about 35 Ω/sq.

### BRIEF DESCRIPTION OF THE DRAWINGS

So that the manner in which the above recited features of the present disclosure can be understood in detail, a more particular description of the disclosure, briefly summarized above, can be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a flow chart illustrating a method of processing a substrate, according to one or more embodiments described and discussed herein.

FIG. 2 depicts a schematic top view of a processing system that can be used to perform the method illustrated by the flow chart of FIG. 1, according to one or more embodiments described and discussed herein.

To facilitate understanding, identical reference numerals have been used, where possible, to designate identical elements that are common to the Figures. It is contemplated that elements and features of one or more embodiments can be beneficially incorporated in other embodiments.

### DETAILED DESCRIPTION

Embodiments of the present disclosure generally relate to methods for preparing or forming metal silicides on silicon substrates. In one or more embodiments, a method of forming the metal silicide includes a cleaning process, a deposition process, and then a silicidation process. During a cleaning process, a substrate containing a native oxide and/or other contaminant is cleaned or otherwise removed to reveal the silicon surface of the substrate. Thereafter, a metallic layer (e.g., Ti, Co, Ni, Mo) is deposited or otherwise formed on the silicon surface during the deposition process. Subsequently, during the silicidation process, the substrate containing the metallic layer is heated to produce the metal silicide layer from the reaction between metal of the metallic layer and silicon of the silicon substrate. The substrate is heated within a chemically reducing environment or process region. For example, the substrate is heated within an environment or process region containing hydrogen gas (H₂) during the silicidation process. The metal silicide layers produced by the silicidation process described and discussed herein have lower electrical resistance than metal silicides formed by other processes.

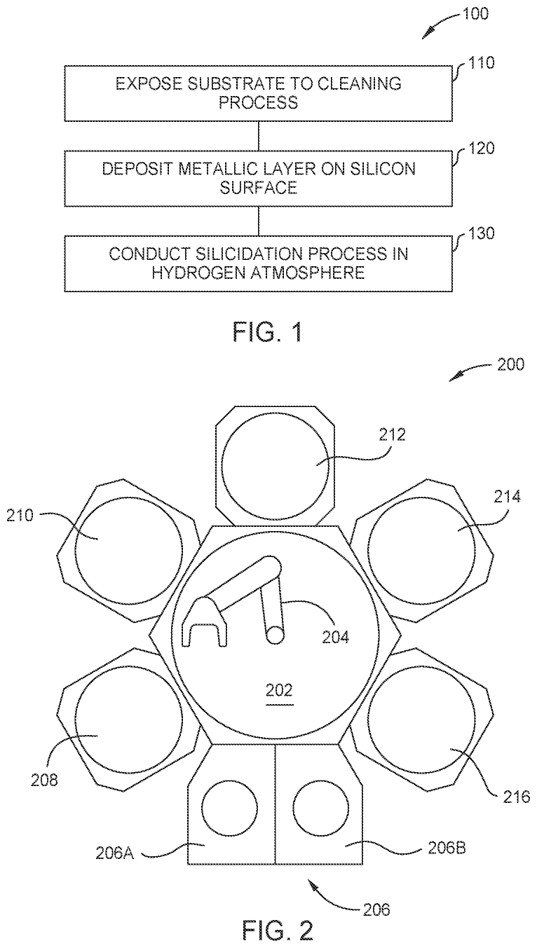

FIG. 1 is a flow chart illustrating a method 100 for processing a workpiece, such as substrate, according to one or more embodiments described and discussed herein. The method 100 includes exposing the substrate to a cleaning process at operation 110, depositing a metallic layer on the cleaned silicon surface of the substrate at operation 120, and conducting a silicidation process in a reducing atmosphere at operation 130. In one or more embodiments, the method 100 can be conducted or otherwise performed in three, four, five, or more processing chambers contained on a cluster tool. For example, the cleaning process can be performed or conducted in a first processing chamber, the deposition process can be performed or conducted in a second processing chamber, and the silicidation process can be performed or conducted in a third processing chamber. Each of the first, second, and third processing chambers can be independently fluidly coupled to a transfer chamber within the cluster tool or other processing system.

At operation 110, a substrate containing a native oxide, a produced oxide, and/or other contaminant is cleaned or otherwise removed to reveal the silicon surface of the substrate. In one or more embodiments, the cleaning process includes exposing the oxide and/or contaminant on the substrate to a plasma formed from a cleaning gas. The cleaning gas can be or include nitrogen trifluoride, ammonia, argon, hydrogen (H₂), or any combination thereof. In other embodiments, the cleaning process includes exposing the substrate to a cleaning solution during a wet clean process and thereafter to a dry clean process. The wet clean process can include exposing the substrate to acidic solution containing hydrogen fluoride, sulfuric acid, sulfonic acid, and/or other acids, or to basic solutions (e.g., ammonium hydroxide or amine solutions), and/or other cleaning solutions. The dry clean process can include exposing the substrate to a plasma, such as the plasma formed from the cleaning gas.

The substrate is cleaned and/or etched for a predetermined time during the cleaning process. The substrate can be exposed to a plasma, a cleaning gas, and/or a cleaning solution for about 5 seconds, about 10 seconds, about 15 seconds, about 20 seconds, about 30 seconds, about 45 seconds, about 60 seconds, about 90 seconds, or about 2 minutes to about 2.5 minutes, about 3 minutes, about 5 minutes, about 10 minutes, about 15 minutes, about 20 minutes, about 30 minutes, about 45 minutes, about 60 minutes, about 75 minutes, about 90 minutes, about 120 minutes, about 150 minutes, or longer during the cleaning process. For example, the substrate can be exposed to a plasma, a cleaning gas, and/or a cleaning solution for about 5 seconds to about 150 minutes, about 5 seconds to about 120 minutes, about 5 seconds to about 90 minutes about 5 seconds to about 75 minutes about 5 seconds to about 60 minutes, about 5 seconds to about 45 minutes, about 5 seconds to about 30 minutes, about 5 seconds to about 20 minutes, about 5 seconds to about 10 minutes, about 5 seconds to about 5 minutes, about 5 seconds to about 2 minutes, about 5 seconds to about 90 seconds, about 5 seconds to about 60 seconds, about 5 seconds to about 30 seconds, about 60 seconds to about 150 minutes, about 60 seconds to about 120 minutes, about 60 seconds to about 90 minutes about 60 seconds to about 75 minutes about 60 seconds to about 60 minutes, about 60 seconds to about 45 minutes, about 60 seconds to about 30 minutes, about 60 seconds to about 20 minutes, about 60 seconds to about 10 minutes, about 60 seconds to about 5 minutes, about 60 seconds to about 2 minutes, about 60 seconds to about 90 seconds, about 5 minutes to about 150 minutes, about 5 minutes to about 120 minutes, about 5 minutes to about 90 minutes about 5 minutes to about 75 minutes about 5 minutes to about 60 minutes, about 5 minutes to about 45 minutes, about 5 minutes to about 30 minutes, about 5 minutes to about 20 minutes, or about 5 minutes during the cleaning process.

At operation 120, a metallic layer is deposited or otherwise formed on the silicon surface of the substrate during the deposition process. The metallic layer can be or include one or more metals, such as titanium, cobalt, nickel, molybdenum, alloys thereof, or any combination thereof. The type of metal for the metallic layer is determined based on the type of metal silicide desired to be formed at operation 130.

The metallic layer can be formed or otherwise produced on the silicon surface of the substrate by one or more vapor deposition processes. The vapor deposition process can be or include a physical vapor deposition (PVD) process, a sputtering process, a thermal chemical vapor deposition (CVD) process, a plasma-enhanced CVD (PE-CVD) process, a pulsed-CVD process, a thermal atomic layer deposition (ALD) process, a plasma-enhanced ALD (PE-ALD) process, or any combination thereof. In one or more examples, a metallic layer containing metallic titanium is deposited by a PVD process or an ALD process. In other examples, a metallic layer containing metallic cobalt is deposited by a PVD process. In other examples, a metallic layer containing metallic nickel is deposited by a CVD process or a PVD process.

In one or more embodiments, the metallic layer is deposited on the silicon surface by PVD during the deposition process. The substrate is heated and/or maintained at a temperature of about 20° C., about 23° C. (e.g., about room temperature), about 25° C., about 30° C., about 50° C., about 80° C., or about 100° C. to about 120° C., about 150° C., about 200° C., about 250° C., about 300° C., about 350° C., about 400° C., about 450° C., or about 500° C. during a PVD process or other deposition process. For example, the substrate is heated and/or maintained at a temperature of about 23° C. to about 500° C., about 23° C. to about 450° C., about 23° C. to about 400° C., about 23° C. to about 350° C., about 23° C. to about 300° C., about 23° C. to about 250° C., about 23° C. to about 200° C., about 23° C. to about 150° C., about 23° C. to about 120° C., about 23° C. to about 100° C., about 23° C. to about 80° C., about 23° C. to about 50° C., about 50° C. to about 500° C., about 50° C. to about 450° C., about 50° C. to about 400° C., about 50° C. to about 350° C., about 50° C. to about 300° C., about 50° C. to about 250° C., about 50° C. to about 200° C., about 50° C. to about 150° C., about 50° C. to about 120° C., about 50° C. to about 100° C., about 50° C. to about 80° C., about 100° C. to about 500° C., about 100° C. to about 450° C., about 100° C. to about 400° C., about 100° C. to about 350° C., about 100° C. to about 300° C., about 100° C. to about 250° C., about 100° C. to about 200° C., about 100° C. to about 150° C., or about 100° C. to about 120° C. during a PVD process or other deposition process.

In other embodiments, the substrate is heated and/or maintained at a temperature of about 20° C., about 23° C. (e.g., about room temperature), about 25° C., about 30° C., about 50° C., about 80° C., or about 100° C. to about 120° C., about 150° C., about 200° C., about 250° C., about 300° C., about 350° C., about 400° C., about 450° C., about 500° C., about 550° C., or about 600° C. during a CVD process, an ALD process, or other deposition process. For example, the substrate is heated and/or maintained at a temperature of about 23° C. to about 600° C., about 23° C. to about 550° C., about 23° C. to about 500° C., about 23° C. to about 450° C., about 23° C. to about 400° C., about 23° C. to about 350° C., about 23° C. to about 300° C., about 23° C. to about 250° C., about 23° C. to about 200° C., about 23° C. to about 150° C., about 23° C. to about 120° C., about 23° C. to about 100° C., about 23° C. to about 80° C., about 23° C. to about 50° C., about 50° C. to about 600° C., about 50° C. to about 450° C., about 50° C. to about 400° C., about 50° C. to about 350° C., about 50° C. to about 300° C., about 50° C. to about 250° C., about 50° C. to about 200° C., about 50° C. to about 150° C., about 50° C. to about 120° C., about 50° C. to about 100° C., about 50° C. to about 80° C., about 100° C. to about 600° C., about 100° C. to about 450° C., about 100° C. to about 400° C., about 100° C. to about 350° C., about 100° C. to about 300° C., about 100° C. to about 250° C., about 100° C. to about 200° C., about 100° C. to about 150° C., or about 100° C. to about 120° C. during a CVD process, an ALD process, or other deposition process.

The metallic layer can have a thickness of about 10 Å, about 15 Å, about 20 Å, about 25 Å, about 30 Å, about 40 Å, about 50 Å, or about 60 Åto about 70 Å, about 80 Å, about 100 Å, about 110 Å, about 130 Å, about 150 Å, about 180 Å, about 200 Å, about 250 Å, about 300 Å, about 400 Å, about 500 Å, or greater. For example, the metallic layer can have a thickness of about 10 Åto about 500 Å, about 10 Åto about 350 Å, about 10 Åto about 200 Å, about 10 Åto about 150 Å, about 10 Åto about 120 Å, about 10 Åto about 100 Å, about 10 Åto about 75 Å, about 10 Åto about 50 Å, about 10 Åto about 30 Å, about 10 Åto about 20 Å, about 25 Åto about 350 Å, about 25 Åto about 200 Å, about 25 Åto about 150 Å, about 25 Åto about 120 Å, about 25 Åto about 100 Å, about 25 Åto about 75 Å, about 25 Åto about 50 Å, about 25 Åto about 30 Å, about 50 Åto about 350 Å, about 50 Åto about 200 Å, about 50 Åto about 150 Å, about 50 Åto about 120 Å, about 50 Åto about 100 Å, about 50 Åto about 75 Å, about 100 Åto about 500 Å, about 100 Åto about 350 Å, about 100 Åto about 200 Å, about 100 Åto about 150 Å, or about 100 Åto about 120 Å.

At operation 130, the substrate containing the metallic layer is heated to produce the metal silicide layer from the reaction between metal of the metallic layer and silicon of the silicon substrate during the silicidation process. The substrate is heated within a chemically reducing environment or process region. For example, the substrate is heated within an environment or process region containing hydrogen gas (H₂) and/or another reducing reagent during the silicidation process. The hydrogen gas and/or other reducing reagent assists in the production of the metal silicide during the silicidation process. The metal silicide layers produced by the silicidation process described and discussed herein have lower electrical resistance than metal silicides formed by other processes which do not utilize an environment or process region containing hydrogen gas (H₂) and/or other reducing reagents. For example, when metal silicides are formed by other processes which heat the substrate in an environment or process region containing nitrogen (N₂), argon, helium, or combinations thereof, the electrical resistance of these metal silicides are much greater than the metal silicide layers produced by the silicidation process described and discussed herein.

Depending on the composition of the metallic layer, the metal silicide layer can be or include titanium silicide, cobalt silicide, nickel silicide, molybdenum silicide, alloys thereof, or any combination thereof. In one or more examples, the metal silicide layer can be or include titanium silicide having the chemical formula TiSi₂. In other examples, the metal silicide layer can be or include titanium silicide having the chemical formula TiSiₓ, where x is from about 1.5, about 1.55, about 1.6, about 1.65, about 1.7, or about 1.75 to about 1.8, about 1.85, about 1.9, about 1.95, about 1.96, about 1.97, about 1.98, about 1.99, or greater. In some examples, the metal silicide layer can be or include cobalt silicide having the chemical formula CoSi₂. In other examples, the metal silicide layer can be or include cobalt silicide having the chemical formula CoSiₓ, where x is from about 1.5, about 1.55, about 1.6, about 1.65, about 1.7, or about 1.75 to about 1.8, about 1.85, about 1.9, about 1.95, about 1.96, about 1.97, about 1.98, about 1.99, or greater.

The silicidation process includes heating and/or maintaining the substrate containing the metallic layer on the silicon surface at a predetermined temperature for a predetermined time. The substrate is heated to and/or maintained at a temperature of about 500° C., about 550° C., about 600° C., about 650° C., about 700° C., or about 750° C. to about 800° C., about 850° C., about 900° C., about 950° C., about 1,000° C., about 1,050° C., about 1,100° C., about 1,150° C., about 1,200° C., about 1,300° C., or greater during the silicidation process. For example, the substrate is heated to and/or maintained at a temperature of about 500° C. to about 1,300° C., about 500° C. to about 1,200° C., about 500° C. to about 1,100° C., about 500° C. to about 1,000° C., about 500° C. to about 900° C., about 500° C. to about 850° C., about 500° C. to about 750° C., about 500° C. to about 650° C., about 500° C. to about 600° C., about 650° C. to about 1,300° C., about 650° C. to about 1,200° C., about 650° C. to about 1,100° C., about 650° C. to about 1,000° C., about 650° C. to about 900° C., about 650° C. to about 850° C., about 650° C. to about 750° C., about 650° C. to about 700° C., about 850° C. to about 1,300° C., about 850° C. to about 1,200° C., about 850° C. to about 1,100° C., about 850° C. to about 1,000° C., or about 850° C. to about 900° C. during the silicidation process.

The substrate is heated for a predetermined time during the silicidation process. The heating may occur in a period of second to minutes depending on thermal technique. The substrate is heated to and/or maintained at the process temperature for about 5 seconds, about 10 seconds, about 15 seconds, about 20 seconds, about 30 seconds, about 45 seconds, about 60 seconds, about 90 seconds, or about 2 minutes to about 2.5 minutes, about 3 minutes, about 5 minutes, about 10 minutes, about 15 minutes, about 20 minutes, about 30 minutes, about 45 minutes, about 60 minutes, about 75 minutes, about 90 minutes, about 120 minutes, about 150 minutes, or longer during the silicidation process. For example, the substrate is heated to and/or maintained at the process temperature for about 5 seconds to about 150 minutes, about 5 seconds to about 120 minutes, about 5 seconds to about 90 minutes about 5 seconds to about 75 minutes about 5 seconds to about 60 minutes, about 5 seconds to about 45 minutes, about 5 seconds to about 30 minutes, about 5 seconds to about 20 minutes, about 5 seconds to about 10 minutes, about 5 seconds to about 5 minutes, about 5 seconds to about 2 minutes, about 5 seconds to about 90 seconds, about 5 seconds to about 60 seconds, about 5 seconds to about 30 seconds, about 60 seconds to about 150 minutes, about 60 seconds to about 120 minutes, about 60 seconds to about 90 minutes about 60 seconds to about 75 minutes about 60 seconds to about 60 minutes, about 60 seconds to about 45 minutes, about 60 seconds to about 30 minutes, about 60 seconds to about 20 minutes, about 60 seconds to about 10 minutes, about 60 seconds to about 5 minutes, about 60 seconds to about 2 minutes, about 60 seconds to about 90 seconds, about 5 minutes to about 150 minutes, about 5 minutes to about 120 minutes, about 5 minutes to about 90 minutes about 5 minutes to about 75 minutes about 5 minutes to about 60 minutes, about 5 minutes to about 45 minutes, about 5 minutes to about 30 minutes, about 5 minutes to about 20 minutes, or about 5 minutes to about 10 minutes during the silicidation process.

In one or more examples, the silicidation process includes heating the substrate to a temperature of about 500° C. to about 1,200° C. for about 5 seconds to about 120 minutes. In other examples, the silicidation process includes heating the substrate to a temperature of about 650° C. to about 850° C. for about 10 seconds to about 5 minutes. In some examples, the silicidation process includes heating the substrate to a temperature of about 680° C. to about 820° C. for about 20 seconds to about 2 minutes or about 30 seconds to about 90 seconds.

The processing chamber contains the workpiece or the substrate in a chemically reducing environment of the process region during the silicidation process. The process region is maintained at a pressure of about 760 Torr or less. The process region is maintained at a pressure of about 10 mTorr, about 20 mTorr, about 50 mTorr, about 100 mTorr, about 250 mTorr, about 500 mTorr, about 800 mTorr, or about 1 Torr to about 5 Torr, about 10 Torr, about 50 Torr, about 100 Torr, about 200 Torr, about 350 Torr, about 500 Torr, about 650 Torr, about 750 Torr, less than 760 Torr, or about 760 Torr during the silicidation process. The process region is maintained at a pressure of about 10 mTorr to less than 760 Torr, about 10 mTorr to about 750 Torr, about 10 mTorr to about 500 Torr, about 10 mTorr to about 300 Torr, about 10 mTorr to about 100 Torr, about 10 mTorr to about 50 Torr, about 10 mTorr to about 10 Torr, about 10 mTorr to about 1 Torr, about 10 mTorr to about 500 mTorr, about 10 mTorr to about 100 mTorr, about 500 mTorr to less than 760 Torr, about 500 mTorr to about 750 Torr, about 500 mTorr to about 500 Torr, about 500 mTorr to about 300 Torr, about 500 mTorr to about 100 Torr, about 500 mTorr to about 50 Torr, about 500 mTorr to about 10 Torr, about 500 mTorr to about 1 Torr, about 10 Torr to less than 760 Torr, about 10 Torr to about 750 Torr, about 10 Torr to about 500 Torr, about 10 Torr to about 300 Torr, about 10 Torr to about 100 Torr, or about 10 Torr to about 50 Torr during the silicidation process.

In one or more examples, the process region containing hydrogen gas is maintained at a pressure of about 10 mTorr to about 760 Torr within a processing chamber during the silicidation process. In other examples, the process region containing hydrogen gas is maintained at a pressure of about 250 mTorr to less than 760 Torr within a processing chamber during the silicidation process. In some examples, the process region containing hydrogen gas is maintained at a pressure of about 10 Torr to less than 760 Torr within a processing chamber during the silicidation process. In other examples, the process region containing hydrogen gas is maintained at a pressure of about 250 mTorr to less than 100 Torr within a processing chamber during the silicidation process. In one or more examples, the process region containing hydrogen gas is maintained at a pressure of about 10 mTorr to about 10 Torr within a processing chamber during the silicidation process.

The metal silicide layer has a thickness greater than the metallic layer from which the metal silicide layer was formed if the majority or all of the metallic layer is consumed during the silicidation process. The thickness of the metal silicide layer can be about 1.2 times, about 1.5 times, or about 1.8 times to about 2 times, about 2.2 times, about 2.5 times, about 2.8 times, about 3 times, or greater, than the thickness of the metallic layer consumed by the silicidation process. The metal silicide layer can have a thickness of about 10 Å, about 15 Å, about 20 Å, about 25 Å, about 30 Å, about 40 Å, about 50 Å, about 80 Å, or about 100 Åto about 110 Å, about 130 Å, about 150 Å, about 180 Å, about 200 Å, about 250 Å, about 300 Å, about 350 Å, about 400 Å, about 500 Å, about 750 Å, or greater. For example, the metal silicide layer can have a thickness of about 10 Åto about 750 Å, about 10 Åto about 500 Å, about 10 Åto about 350 Å, about 10 Åto about 200 Å, about 10 Åto about 150 Å, about 10 Åto about 120 Å, about 10 Åto about 100 Å, about 10 Åto about 75 Å, about 10 Åto about 50 Å, about 10 Åto about 30 Å, about 25 Åto about 500 Å, about 25 Åto about 350 Å, about 25 Åto about 200 Å, about 25 Åto about 150 Å, about 25 Åto about 120 Å, about 25 Åto about 100 Å, about 25 Åto about 75 Å, about 25 Åto about 50 Å, about 25 Åto about 30 Å, about 100 Åto about 750 Å, about 100 Åto about 500 Å, about 100 Åto about 350 Å, about 100 Åto about 200 Å, about 100 Åto about 150 Å, or about 100 Åto about 120 Å.

The metal silicide layer prepared or otherwise produced by the silicidation process has a relatively low electrical resistance compared to metal silicide layers produced by other methods. The metal silicide layer prepared or otherwise produced by the silicidation process has an electrical resistance of less than 50 Ω/square (sq), such as about 2 Ω/sq, about 4 Ω/sq, about 5 Ω/sq, about 8 Ω/sq, about 10 Ω/sq, about 12 Ω/sq, about 15 Ω/sq, about 18 Ω/sq, about 20 Ω/sq, or about 22 Ω/sq to about 25 Ω/sq, about 28 Ω/sq, about 30 Ω/sq, about 32 Ω/sq, about 35 Ω/sq, about 38 Ω/sq, about 40 Ω/sq, about 42 Ω/sq, about 45 Ω/sq, or about 48 Ω/sq. For example, the metal silicide layer has an electrical resistance of about 2 Ω/sq to less than 50 Ω/sq, about 4 Ω/sq to less than 50 Ω/sq, about 4 Ω/sq to about 48 Ω/sq, about 4 Ω/sq to about 40 Ω/sq, about 4 Ω/sq to about 35 Ω/sq, about 4 Ω/sq to about 30 Ω/sq, about 4 Ω/sq to about 28 Ω/sq, about 4 Ω/sq to about 25 Ω/sq, about 4 Ω/sq to about 22 Ω/sq, about 4 Ω/sq to about 20 Ω/sq, about 4 Ω/sq to about 15 Ω/sq, about 4 Ω/sq to about 12 Ω/sq, about 4 Ω/sq to about 10 Ω/sq, about 4 Ω/sq to about 8 Ω/sq, about 10 Ω/sq to less than 50 Ω/sq, about 10 Ω/sq to about 48 Ω/sq, about 10 Ω/sq to about 40 Ω/sq, about 10 Ω/sq to about 35 Ω/sq, about 10 Ω/sq to about 30 Ω/sq, about 10 Ω/sq to about 28 Ω/sq, about 10 Ω/sq to about 25 Ω/sq, about 10 Ω/sq to about 22 Ω/sq, about 10 Ω/sq to about 20 Ω/sq, about 10 Ω/sq to about 15 Ω/sq, or about 10 Ω/sq to about 12 Ω/sq.

In one or more embodiments, a method for preparing or forming a metal silicide includes removing a native oxide and/or contaminant from the substrate to reveal the silicon surface of the substrate during a cleaning process. Thereafter, a metallic layer containing titanium is deposited or otherwise formed on the silicon surface during a deposition process. Subsequently, the substrate containing the metallic layer is heated while being within a process region containing hydrogen gas during a silicidation process. A metal silicide layer containing titanium is formed or otherwise produced on the substrate from a chemical reaction between metal atoms of the metallic layer and the silicon atoms of the silicon surface. The metal silicide layer has an electrical resistance of less than 50 Ω/sq.

In other embodiments, a method for preparing or forming a metal silicide includes removing a native oxide and/or contaminant from the substrate to reveal the silicon surface of the substrate during a cleaning process. Thereafter, a metallic layer containing titanium is deposited or otherwise formed on the silicon surface during a PVD process. The substrate is maintained at a temperature of about 23° C. to about 450° C. during the PVD process. The method also includes exposing the substrate to a silicidation process to produce a metal silicide layer containing titanium on the substrate from the metallic layer and the silicon surface. The silicidation process includes heating the substrate within a process region containing hydrogen gas to a temperature of about 500° C. to about 1,100° C. The metal silicide layer has an electrical resistance of about 4 Ω/sq to about 35 Ω/sq.

FIG. 2 is a schematic top view of a processing system 200 that can be used to perform or conduct the process 100 illustrated by the flow chart of FIG. 1, according to embodiments discussed and described herein. In some examples, the processing system 200 can be or include a cluster tool. In one or more aspects, the processing system 200 can be the CENTURA® system, commercially available from Applied Materials, Inc. of Santa Clara, Calif. A transfer robot 204 of any convenient type is disposed in a transfer chamber 202 of the processing system 200. A load-lock 206, with two load-lock chambers 206A, 206B is coupled to the transfer chamber 202. A plurality of processing chambers 208, 210, 212, 214, and 216 are also coupled to the transfer chamber 202. The plurality of processing chamber 208, 210, 212, 214, and 216 may include one or more cleaning chambers, one or more plasma chambers, one or more vapor deposition chambers, one or more annealing chambers, one or more silicide chambers, and/or other types of chambers.

Each of the processing chambers 208, 210 can independently be cleaning chambers configured to clean a substrate prior to the deposition of metallic films or materials. The substrate can be cleaned to remove the native oxide and/or other contaminants from the substrate to reveal and/or produce the silicon surface of the substrate during the cleaning process. The processing chambers 208, 210 can be used to perform the cleaning process as discussed above in operation 110. In one or more configurations, the processing chamber 208 can be used to conduct a wet clean process and the processing chamber 210 can be used to conduct a dry clean process. In one or more embodiments, each of the processing chambers 208, 210 can independently be a pre-clean chamber using an in situ plasma source and/or a remote plasma source (RPS) for generating a plasma. The cleaning process can include exposing the native oxide layer and/or other contaminant on the substrate to a plasma formed from a cleaning gas within the pre-clean chamber. The cleaning gas can be or include nitrogen trifluoride, ammonia, argon, hydrogen (H₂), plasmas thereof, or any combination thereof.

In one or more embodiments, each of the processing chambers 208, 210 can independently be an TERSA® Pre-Clean™ chamber available from Applied Materials, Inc. of Santa Clara, Calif. The processing chambers 208, 210 use electrically neutral radicals (e.g., hydrogen radicals) to react with and clean oxides and/or contaminants on a substrate. In other embodiments, each of the processing chambers 208, 210 can independently be an AKTIV Pre-Clean™ chamber available from Applied Materials, Inc. of Santa Clara, Calif. The processing chambers 208, 210 use electrically neutral radicals (e.g., hydrogen radicals) to react with and clean oxides and/or contaminants on a substrate.

The processing chambers 208, 210 can independently be a cleaning chamber configured to clean a substrate prior to depositing a metallic layer thereon. The cleaning process can include exposing the substrate to a plasma formed from a cleaning gas which can be or include nitrogen trifluoride, ammonia, argon, hydrogen (H₂), plasmas thereof, or any combination thereof. For example, the processing chambers 208 and 210 can independently be a capacitively coupled processing chamber. In one or more embodiments, each of the processing chambers 208, 210 can independently be a SICONI® Pre-clean chamber, commercially available from Applied Materials, Inc. of Santa Clara, Calif.

In other embodiments, each of the processing chambers 208, 210 can independently be an etching chamber configured to etch material (e.g., oxides and/or contaminants) from a substrate. For example, the processing chambers 208, 210 can independently be a plasma chamber such as an ICP plasma chamber. In one or more embodiments, the processing chamber 208 is a Centura® Advantedge™ Mesa™ Etch chamber available from Applied Materials, Inc. of Santa Clara, Calif.

The processing chamber 212 can be used to perform downstream processing after cleaning, such as depositing one or more metals or other materials on the silicon surface of the substrate. For example, one or more metallic layers and/or other type of layers can be deposited or otherwise formed on the silicon surface during the deposition process. The processing chamber 212 can be used to perform the deposition process as discussed above in operation 120. The processing chamber 212 can be a vapor deposition chamber, such as a PVD chamber, a sputtering chamber, a thermal CVD chamber, a PE-CVD chamber, a pulsed-CVD chamber, a thermal ALD chamber, a PE-ALD chamber, or any combination thereof during the deposition process. In one or more embodiments, the processing chamber 212 can be a CIRRUSTM™ PVD chamber available from Applied Materials, Inc. of Santa Clara, Calif.

The processing chamber 214 can be a thermal processing chamber configured to provide a controlled thermal cycle that heats the substrate. Alternatively, the processing chamber 214 can be a plasma annealing chamber configured to provide a plasma and controlled thermal cycle while processing and heating the substrate. The processing chamber 214 can be used to heat the substrate to a predetermined temperature and to perform or otherwise conduct the silicidation process as discussed above in operation 130.

In one or more examples, the processing chamber 214 is a RADIANCE® RTP chamber available from Applied Materials, Inc. of Santa Clara, Calif. In other examples, the processing chamber 214 is a VANTAGE® RADOX™ RTP chamber available from Applied Materials, Inc. of Santa Clara, Calif. The processing chamber 214 is fluidly coupled to one or more sources of an annealing gas or a process gas. For example, the processing chamber can be fluidly coupled to a source of hydrogen gas.

In one or more embodiments, the processing chamber 216 can be another chamber such as any one of the processing chambers 208, 210, 212, or 214, as described and discussed above. For example, the processing chamber 216 can be a cleaning chamber configured to clean a substrate (e.g., after deposition), a plasma chamber, a thermal processing chamber configured to provide a controlled thermal cycle that heats a substrate, a deposition chamber configured to deposit another material, or another type of processing chamber. In some embodiments, the processing chamber 216 can be absent or simply not used during an operation.

During processing, a substrate that is to be processed may arrive to the processing system 200 in a pod (not shown). The substrate is introduced into the processing system 200. The substrate is transferred from the pod to the vacuum compatible load-lock 206A, 206B by the factory interface robot (not shown). The substrate is then handled by the transfer robot 204 in the transfer chamber 202, which is generally kept in a vacuum state. The transfer robot 204 then loads the substrate into either the processing chamber 208 or the processing chamber 210 for cleaning of the substrate, as described in operation 110. Upon completion of the cleaning and removing oxides and/or contaminants, the transfer robot 204 then picks up the substrate from the processing chamber 208 or 210 and loads the substrate into the processing chamber 212 for a deposition process, such as a PVD, CVD, or ALD process to form a metallic layer on the silicon surface of the substrate, as described in operation 120. The transfer robot 204 then picks up the substrate from the processing chamber 212 and may load the substrate into the processing chamber 216 for a silicidation process to produce a metal silicide layer on the substrate from the metallic layer and the silicon surface, as described in operation 130. Optionally, in one or more embodiments, the transfer robot 204 then picks up the substrate from the processing chamber 214 and loads the substrate into the processing chamber 216 for conducting or performing any other desired process to the substrate containing the metal silicide layer.

The transfer chamber 202 may remain under vacuum and/or at a pressure below atmosphere during the process. The vacuum level of the transfer chamber 202 can be adjusted to match the vacuum level of corresponding processing chambers. For example, when transferring a substrate from a transfer chamber 202 into a processing chamber (or vice versa), the transfer chamber 202 and the processing chamber can be maintained at the same vacuum level. Then, when transferring a substrate from the transfer chamber to the load lock chamber or batch load lock chamber (or vice versa), the transfer chamber vacuum level may match the vacuum level of the load-lock chamber 206A, 206B even through the vacuum level of the load-lock chamber and the processing chamber can be different.

Methods described and discussed herein provide many advantages over previous silicide process techniques. The substrate is heated within a chemically reducing environment or process region. For example, the substrate is heated within an environment or process region containing hydrogen gas during the silicidation process. The silicidation process described and discussed herein provides thermal stability by reducing or eliminating agglomeration to the metal silicide layer which otherwise would cause film discontinuity and greater resistivity (Rc). The metal silicide layers produced by the silicidation process described and discussed herein have lower electrical resistance than metal silicides formed by other processes.

While the foregoing is directed to embodiments of the disclosure, other and further embodiments can be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. What is claimed is:
1 A method of forming a metal silicide, comprising:
removing a native oxide from a substrate to reveal a silicon surface of the substrate during a cleaning process;
depositing a metallic layer on the silicon surface during a deposition process; and
heating the substrate contained within a process region comprising hydrogen gas (H₂) during a silicidation process to produce a metal silicide layer on the substrate from the metallic layer and the silicon surface.

2. The method of claim 1, wherein the cleaning process comprises exposing the native oxide layer to a plasma formed from a cleaning gas.

3. The method of claim 2, wherein the cleaning gas comprises nitrogen trifluoride, ammonia, argon, hydrogen (H₂), or any combination thereof.

4. The method of claim 1, wherein the metallic layer is deposited on the silicon surface by physical vapor deposition (PVD) during the deposition process.

5. The method of claim 4, wherein the substrate is maintained at a temperature of about 23° C. to about 450° C. during the deposition process.

6. The method of claim 1, wherein the metallic layer is deposited on the silicon surface a thermal chemical vapor deposition (CVD) process, a plasma-enhanced CVD (PE-CVD) process, a pulsed-CVD process, a thermal atomic layer deposition (ALD) process, a plasma-enhanced ALD (PE-ALD) process, or any combination thereof during the deposition process.

7. The method of claim 6, wherein the substrate is maintained at a temperature of about 23° C. to about 600° C. during the deposition process.

8. The method of claim 1, wherein the metallic layer comprises titanium, cobalt, nickel, molybdenum, alloys thereof, or any combination thereof.

9. The method of claim 1, wherein the metallic layer has a thickness of about 10 Å to about 200 Å.

10. The method of claim 1, wherein the silicidation process comprises heating the substrate to a temperature of about 500° C. to about 1,200° C. for about 5 seconds to about 120 minutes.

11. The method of claim 1, wherein the silicidation process comprises heating the substrate to a temperature of about 650° C. to about 850° C. for about 10 seconds to about 5 minutes.

12. The method of claim 1, wherein the process region is maintained at a pressure of about 10 mTorr to about 760 Torr within a processing chamber during the silicidation process.

13. The method of claim 1, wherein the process region is maintained at a pressure of about 250 mTorr to less than 760 Torr within a processing chamber during the silicidation process.

14. The method of claim 1, wherein the metal silicide layer comprises titanium silicide, cobalt silicide, nickel silicide, molybdenum silicide, alloys thereof, or any combination thereof.

15. The method of claim 1, wherein the metal silicide layer has a thickness of about 10 Å to about 500 Å.

16. The method of claim 1, wherein the metal silicide layer has an electrical resistance of less than 50 Ω/square (sq).

17. The method of claim 16, wherein the metal silicide layer has an electrical resistance of about 4 Ω/sq to about 35 Ω/sq.

18. The method of claim 1, wherein the cleaning process is performed in a first processing chamber, the deposition process is performed in a second processing chamber, and the silicidation process is performed in a third processing chamber, and wherein each of the first, second, and third processing chambers is fluidly coupled to a transfer chamber within a processing system.

19. A method of forming a metal silicide, comprising:
removing a native oxide from a substrate to reveal a silicon surface of the substrate during a cleaning process;
depositing a metallic layer comprising titanium on the silicon surface during a deposition process; and
heating the substrate contained within a process region comprising hydrogen gas (H₂) during a silicidation process to produce a metal silicide layer comprising titanium on the substrate from the metallic layer and the silicon surface, wherein the metal silicide layer has an electrical resistance of less than 50 Ω/sq.

20. A method of forming a metal silicide, comprising:
exposing a substrate to a plasma to remove a native oxide disposed on the substrate and to reveal a silicon surface of the substrate;
depositing a metallic layer comprising titanium on the silicon surface during a physical vapor deposition (PVD) process, wherein the substrate is maintained at a temperature of about 23° C. to about 450° C. during the PVD process; and
exposing the substrate to a silicidation process to produce a metal silicide layer comprising titanium on the substrate from the metallic layer and the silicon surface, wherein the silicidation process comprises heating the substrate within a process region comprising hydrogen gas (H₂) to a temperature of about 500° C. to about 1,100° C., and wherein the metal silicide layer has an electrical resistance of about 4 Ω/sq to about 35 Ω/sq.
